(19) United States
(12) Patent Application Publication
(10) Pub. No.: US 2002/0163073 A1
(43) Pub. Date: Nov. 7, 2002

(54) Multi-layer substrate for an IC chip

(76) Inventors: Chung-Ju Wu, Kaohsiung (TW); Chia-Wen Shih, Hsinchu (TW); Chen-Wen Tsai, Hsinchu (JP); Wei-Feng Lin, Hsinchu (TW)

Correspondence Address: BIRCH STEWART KOLASCH & BIRCH, PO BOX 747, FALLS CHURCH, VA, 22040-0747, US

(21) Appl. No.: 09/928,425

(22) Filed: Aug. 14, 2001

(30) Foreign Application Priority Data
May 1, 2001 (TW) 90110413

(51) Int. Cl. H01L 23/053

(52) U.S. Cl. 257/700

(57) ABSTRACT

A multi-layer substrate for an IC chip having a plurality of pads comprises a first layer having a plurality of conducting lines electrically connected to the pads of the IC chip, whereby a first current is generated in the conducting lines, and a second layer has a ground plane electrically connected to a ground, and a plurality of via holes penetrating the second layer and the conducting plane, wherein the via holes are arranged to make a second current in the conducting plane induced by the first current flowing to the ground.

### BACKGROUND OF THE INVENTION

1. Field of the Invention

The present invention relates to a multi-layer substrate for an IC chip, particularly to a multi-layer substrate and a method for arranging the via holes of the substrate, wherein the via holes are arranged to make the mirror current flow more easily to the ground and generate minimal noise in the conducting lines.

2. Description of the Prior Art

FIG. 1 is a diagram showing a conventional multi-layer substrate for an IC chip. The substrate 1 comprises layers 11, 12, 13 and 14. The solder balls 17 are bonded to the bottom of the layer 14 to electrically connect the IC chip 15 to an external device (not shown). Layers 11 and 14 have conducting lines or traces 114 laid on their surfaces (the conducting lines 114 of the layer 14 are not shown). The layers 12 and 13 have conducting planes(not shown in FIG. 1) electrically connected to the ground and a power supply. Furthermore ,the layers 11, 12, 13 and 14 have via holes( FIG. 1 shows only the via holes 111a and 111b of the layer 11). The conducting lines 114 and the conducting planes of different layers are electrically connected by the via holes.

The IC chip 15 is mounted on the layer 11. The chip 15 has pads 151 for inputting and outputting of signals and connecting to a power supply or ground. The pads 151 are electrically connected to the fingers 115 of the layer 11 by the bonding wires 16. The conducting lines 114 electrically connect the fingers 115 to the via holes 111a and via holes 111b surrounded by the via holes 111a. The ground ring 112 and power ring 113 surrounding the chip 15 are electrically connected to the ground and power (conducting) plane of layers 12 and 13 respectively. The pads 151, for connecting to the power supply and ground, are electrically connected to the ground ring 112 and power ring 113 respectively.

FIG. 2 is a diagram showing the layer 12 of the conventional multi-layer substrate 1. As previously described, the layer 12 has a ground (conducting) plane 122 and via holes 121a, 121b and 121c. The via holes 121b surround the via holes 121a which surround the via holes 121c and all of them penetrate the layer 12 and the ground plane 122. The via holes 121a and 121b are electrically isolated from the ground plane 122 and connected to the power (conducting) plane of the layer 13, the layer 14 or the solder balls 17, while the via holes 121c are electrically connected to the ground plane 122. Most of the via holes 121a and 121b connect the pads 151 of the chip 15 for data signal to the solder balls 17(shown in FIG. 1) and the rest of them connect the pads 151 of the chip 15 for power supply to the solder balls 17.

Much noise is generated in the signals transmitted by the conducting lines due to an induced mirror current. Please refer to FIG. 2, in which currents flow through the conducting lines 114 of the layer 11 for signal transmission during the operation of the chip 15. This induces mirror currents to flow through the ground plane 122 of the layer 12 adjacent to the layer 11 in an opposite direction (shown by the arrows in FIG. 2). In the conventional multi-layer substrate, the via holes 121a are closely adjacent and besiege the via holes 121c electrically connected to the ground, which block the path of the mirror current to the ground. These blocked mirror currents generate considerable noise in the signals transmitted by the conducting lines.

### SUMMARY OF THE INVENTION

Therefore, the object of the present invention is to provide a multi-layer substrate for an IC chip which makes the mirror current flow more easily to the ground and thereby eliminate the noise normally associated therewith.

The present invention provides a multi-layer substrate for an IC chip having a plurality of pads comprising: a first layer having a plurality of conducting lines electrically connected to the pads of the IC chip, whereby a first current is generated in the conducting lines, and a second layer having a ground plane electrically connected to a ground, and a plurality of via holes penetrating the second layer and the conducting plane, wherein the via holes are arranged to generate a second current in the conducting plane induced by the first current flowing to the ground.

The present invention further provides a method for arranging via holes of a multi-layer substrate for an IC chip having a plurality of pads, the method comprising the steps of: providing a first layer having a plurality of conducting lines electrically connected to the pads of the IC chip, and a second layer having a ground plane electrically connected to a ground and a plurality of via holes penetrating the second layer and the conducting plane, generating a first current in the conducting lines, which induces a second current in the ground plane, and arranging the via holes to make the second current flowing to the ground.

In the present invention, the via holes on the ground plane are arranged radially and do not block the path of the mirror currents to the ground. The mirror currents flow easily through the ground plane to the ground and, thus, noise is eliminated.

### BRIEF DESCRIPTION OF THE DRAWINGS

The following detailed description, given by way of example and not intended to limit the invention solely to the embodiments described herein, will best be understood in conjunction with the accompanying drawings, in which:

FIG. 1 is a diagram showing a conventional multi-layer substrate for an IC chip.

FIG. 2 is a diagram showing a second layer with a ground plane of the conventional substrate.

FIG. 3 is a diagram showing a second layer with a ground plane according to one embodiment of the invention.

FIG. 4 is a flowchart of the method for arranging via holes of a multi-layer substrate for an IC chip according to one embodiment of the invention.

### DETAILED DESCRIPTION OF THE INVENTION

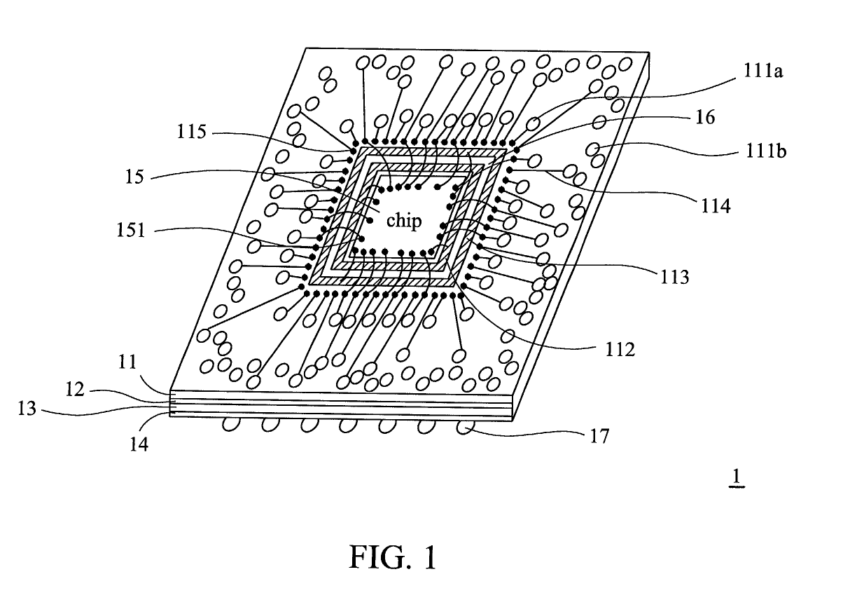

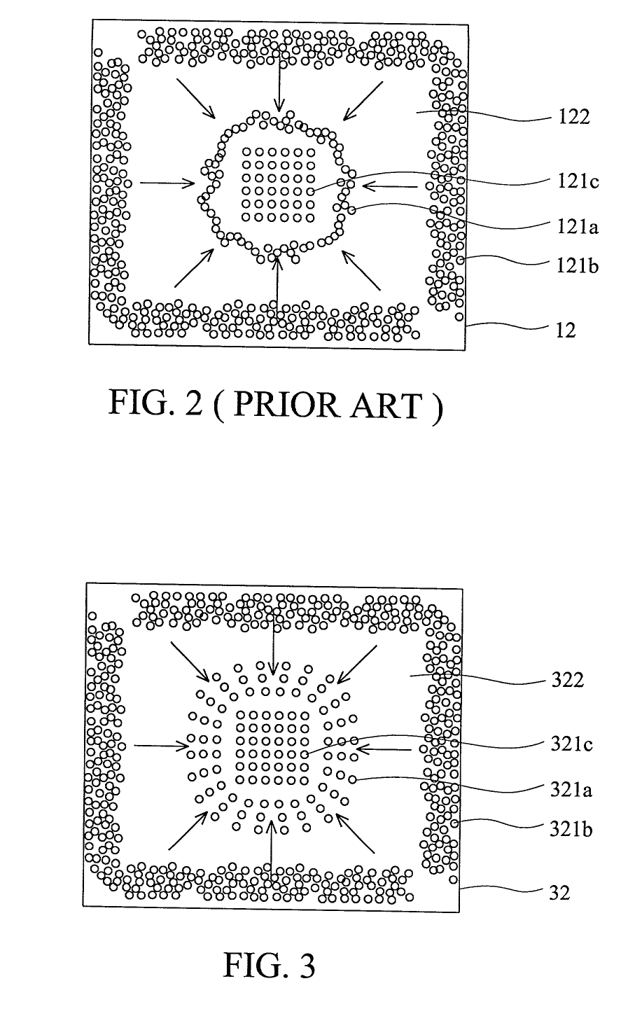

The multi-layer substrate in this embodiment has the same structure as the conventional one, except for the via holes on the ground plane. FIG. 3 is a diagram showing a second layer with a ground plane according to one embodiment of the invention. The layer 32 has a ground (conducting) plane 322 and via holes 321a, 321b and 321c. The via holes 321b surround the via holes 321a which surround the via holes 321c and all of them penetrate the layer 32 and the ground plane 322. The via holes 321a and 321b are electrically isolated from the ground plane 322 and connected to the power (conducting) plane of the layer 33, the layer 34 or the solder balls 17(shown in FIG. 1), while the via holes 321c are electrically connected to the ground plane 322. Most of the via holes 321a and 321b connect the pads 351 of the chip 15 (shown in FIG. 1)for data signal to the solder balls 17(shown in FIG. 1) and the rest of them connect the pads 151 of the chip 15 for power supply to the solder balls 17.

The via holes 321a are arranged radially. Currents flow through the conducting lines 114 (shown in FIG. 1) of the layer 11 (shown in FIG. 1) for signal transmission during the operation of the chip 15. This induces mirror currents to flow through the ground plane 322 of the layer 32 adjacent to the layer 11 in an opposite direction (shown by the arrows in FIG. 3). Since the via holes 121a are arranged radially, there is space between the via holes 321a. Thus, the mirror currents flow through the intervals between the via holes 321a to the via holes 321c electrically connected to the ground. The paths of the mirror currents to the ground are not blocked and the mirror currents easily flow to the ground. Consequently, noise is eliminated.

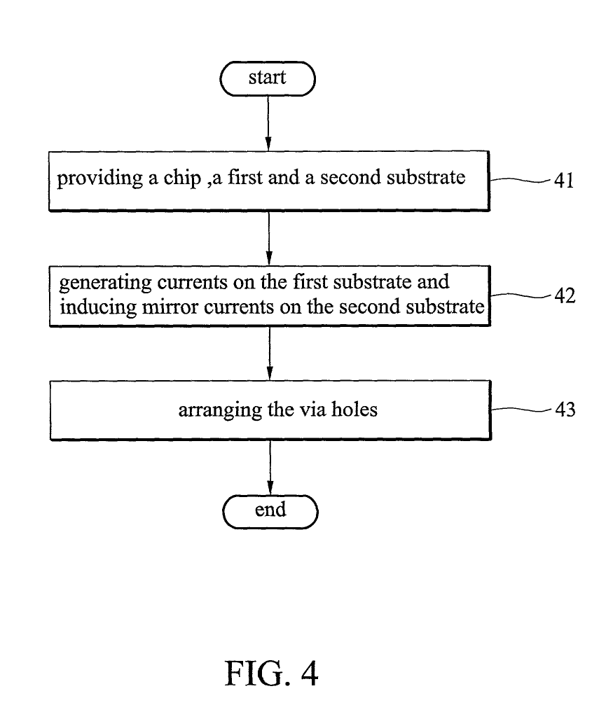

FIG. 4 is a flowchart of the method for arranging via holes of a multi-layer substrate for an IC chip according to one embodiment of the invention.

First, in step 41, in an IC chip, a first and second layer of a multi-layer substrate for the IC chip are provided. The IC chip has pads, the first layer with conducting lines electrically connected to the pads of the IC chip, and the second layer with a ground plane electrically connected to a ground and via holes penetrating the second layer and the conducting plane.

Next, in step 42, currents are generated in the conducting lines, which induce mirror currents in the ground plane during the operation of the IC chip.

Then, in step 43, the via holes are arranged to make the mirror currents flow more easily to the ground. There are two groups of via holes. One group of the via holes is electrically connected to the ground plane and surrounded by the other group which are arranged radially and electrically isolated from the ground plane.

In conclusion, the multi-layer substrate for the IC chip of the invention has isolated via holes on the ground plane radially arranged so that the mirror current paths to the ground are not blocked. This prevents the signals transmitted by the conducting lines from creating interference-generated noise.

While the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A multi-layer substrate for an IC chip having a plurality of pads comprising:
a first layer having a plurality of conducting lines electrically connected to the pads of the IC chip, whereby a first current is generated in the conducting lines; and
a second layer having a ground plane electrically connected to a ground, and a plurality of via holes penetrating the second layer and the conducting plane, wherein the via holes are arranged to create a second current in the conducting plane induced by the first current flowing to the ground.

2. The substrate as claimed in claim 1 wherein the first layer has a ground ring electrically connected to the pads and the conducting plane.

3. The substrate as claimed in claim 1 wherein the first layer has a power ring electrically connected to the pads.

4. The substrate as claimed in claim 3 further comprising a third layer having a power plane electrically connected to the power ring.

5. The substrate as claimed in claim 1 further comprising a fourth layer.

6. The substrate as claimed in claim 5 further comprising a plurality of solder balls bonded to the fourth layer.

7. The substrate as claimed in claim 1 wherein the via holes comprise a plurality of first and second via holes electrically connected and isolated from the ground plane, respectively.

8. The substrate as claimed in claim 7 further comprising a fourth layer and a plurality of solder balls bonded to the fourth layer, wherein the second via holes penetrate the second layer and are electrically connected to the solder balls.

9. The substrate as claimed in claim 7 wherein the first via holes are surrounded by the second via holes.

10. The substrate as claimed in claim 9 wherein the second via holes are arranged radially.

11. The substrate as claimed in claim 9 wherein the via holes further comprise a plurality of third via holes surrounding the second via holes.

12. The substrate as claimed in claim 11 wherein the third via holes are electrically isolated from the ground plane.

13. The substrate as claimed in claim 1, wherein the substrate is a BGA multi-layer substrate.

14. A method for arranging via holes of a multi-layer substrate for an IC chip having a plurality of pads, the method comprising the steps of:
providing a first layer having a plurality of conducting lines electrically connected to the pads of the IC chip, and a second layer having a ground plane electrically connected to a ground and a plurality of via holes penetrating the second layer and the conducting plane;
generating a first current in the conducting lines, which induces a second current in the ground plane; and
arranging the via holes to make the second current flowing to the ground.

15. The method as claimed in claim 14 wherein the via holes comprise first and second via holes, the method further comprising the steps of:
electrically connecting the first via holes to the ground plane and isolating the second via holes from the ground plane;
surrounding the first via holes with the second via holes; and
radially arranging the second via holes.

16. The method as claimed in claim 14 wherein the substrate is a BGA multi-layer substrate.
